(19) United States
(12) Patent Application Publication
(10) Pub. No.: US 2024/0290909 A1
(43) Pub. Date: Aug. 29, 2024

(54) METHOD AND SYSTEM OF PRODUCING MICROSTRUCTURED COMPONENTS

(71) Applicant: 3D-Micromac AG, Chemnitz (DE)

(72) Inventor: Uwe Kober, Chemnitz (DE)

(73) Assignee: 3D-Micromac AG, Chemnitz (DE)

(21) Appl. No.: 18/573,354

(22) PCT Filed: May 25, 2022
(86) PCT No.: PCT/EP2022/064300

§ 371 Date: Dec. 21, 2023

(30) Foreign Application Priority Data
Jun. 22, 2021 (DE) 10 2021 206 403.5

(51) Int. Cl. H01L 33/00

(52) U.S. Cl. CPC H01L 33/0093; H01L 33/0095

(57) ABSTRACT

A method and a system of producing a microstructured component includes a multiplicity of micro-functional elements on a substrate, wherein laser processing is carried out in at least one method stage in a laser processing station under the control of a control unit. One preferred field of application is the production of a micro-LED display including a substrate which carries an array of pixel-forming micro-light-emitting diodes arranged on an electrical supply structure arranged on the substrate.

### TECHNICAL FIELD

This disclosure relates to a method and a system of producing a microstructured component comprising a multiplicity of micro-functional elements on a substrate, wherein laser processing is carried out in at least one method stage in a laser processing station under the control of a control unit. One preferred field of application is the production of a micro-LED display comprising a substrate which carries an array of pixel-forming micro-light-emitting diodes arranged on an electrical supply structure arranged on the substrate.

### BACKGROUND

The term micro-LED-sometimes also called μLED-denotes a flat screen technology based on light-emitting diodes (LEDs). Micro-LED displays are microelectronic components based on arrangements (arrays) of microscopically small light-emitting diodes that form the picture elements of the display, also referred to as pixels. Between the individual μLEDs there are interspaces. Individual pixels may consist of three subpixels, i.e. three μLEDs for red (R), green (G) and blue (B) such that there are interspaces between the μLEDs within a pixel as well. The micro-LEDs are self-luminous, dimmable and able to be switched off completely and therefore do not require a backlight as in liquid crystal displays (for short: LCDs). Micro-LEDs are one example of optoelectronic micro-functional elements of multilayer construction.

Light-emitting diodes (LEDs) are often produced nowadays by p- and n-doped semiconductor layers composed of gallium nitride (GaN) being formed on a sapphire wafer that serves as a growth substrate by epitaxial growth. These layers each have a thickness of a few μm and the total thickness of the various GaN layers can be e.g. less than 10 μm. Prior to further processing, the GaN layers can be structured, for example, by laser processing to produce individual components or prepare the production thereof. A thin, generally metallic connection layer is applied to the GaN layer stack, for example, by vapor deposition. With the aid of this connection layer, the growth substrate with the GaN layer stack situated thereon is connected to a further flat substrate to which the optoelectronically active micro-functional elements are intended to be transferred. The areal connection between the growth substrate and the GaN stack is released for this purpose. As a result, the GaN stack is transferred to the further substrate. The further substrate with the GaN stack carried thereby then serves as a base for further steps of producing the microelectronic component. It can serve as a temporarily utilized transfer substrate for feeding some or all of the transferred micro-functional elements in an ordered arrangement to a downstream process step.

The functional layer stack comprising the further substrate and the GaN layer stack is separated from the growth substrate nowadays usually with the aid of the so-called laser lift-off method (LLO method). In that situation, a buffer layer situated in the boundary region between the growth substrate and the GaN layers is destroyed or decomposed by laser irradiation to leave a thin Ga layer and gaseous nitrogen. The irradiation is effected from the rear side of the growth substrate and through the latter, the laser beam being focused onto the buffer layer or the boundary region. The growth substrate can subsequently be separated from the other layers by external force action.

In the context of micro-LED technology there are further possibilities for utilization of laser processing. They include laser-induced forward transfer (LIFT). Laser-induced forward transfer (LIFT) is a class of methods in which material is transferred from an initial substrate (donor) via a certain flight path to a target substrate (acceptor) by laser radiation. This transfer technique can be utilized e.g. as an alternative to the LLO method to transfer the micro-functional elements from the growth substrate to a transfer substrate. LIFT can also be utilized to transfer the μLEDs from a transfer substrate to the substrate of the microstructured component.

Massively parallel processing has to be realized to be able to transfer a large number of μLEDs economically. This is done using masks having a multiplicity of openings or apertures that split a conditioned laser beam into a corresponding multiplicity of partial beams. The mask openings emitting laser radiation are then imaged onto the processing plane of the laser processing unit.

An overview of the use of laser-based technologies in the fabrication of micro-LEDs may be found in the white paper “MicroLEDs—Laser Processes for Display Production” via the homepage of the company Coherent, administered by Coherent Shared Services B.V., Dieselstraβe 5b, D-64807 Dieburg.

EP 3 742 477 A1 describes a method and an apparatus for transferring components such as e.g. micro-LEDs. A first substrate is equipped with the components. A second substrate is provided with an adhesive layer comprising a hot melt adhesive material. The components on the first substrate are contacted with the adhesive layer on the second substrate while the adhesive layer is melted. The adhesive layer is allowed to solidify to form an adhesive connection between the components and the second substrate. The first and second substrates are moved apart to transfer the components from the first substrate to the second substrate. At least one subset of the components is transferred from the second substrate to a third substrate by light being radiated onto the adhesive layer to form a jet of melted adhesive carrying the components. Further transfer steps can be provided.

There is a need for methods and devices that allow cost-effective and nevertheless high-precision mass production of micro-LED displays and/or other microstructured components having a multiplicity of micro-functional elements on a substrate.

It could therefore be helpful to provide a method and a system of producing microstructured components which allow economic fabrication of such components in conjunction with high quality.

### SUMMARY

I provide a method of producing a microstructured component including a multiplicity of micro-functional elements on a substrate for producing a micro-LED display including a substrate that carries an array of pixel-forming micro-light-emitting diodes on an electrical supply structure, wherein laser processing is carried out in at least one method stage in a laser processing station under control of a control unit, the method including providing a first substrate that carries a multiplicity of micro-functional elements arranged on a first side of the first substrate in a first spatial arrangement; transferring micro-functional elements in a first transfer step from the first substrate to a transfer substrate; and transferring micro-functional elements in a second transfer step from the transfer substrate to a second substrate such that the micro-functional elements are arranged on the second substrate in a second spatial arrangement, wherein the transfer substrate is a dicing tape clamped in stretched fashion in a clamping frame and includes an elastically stretchable base film under surface tension with an adhesive layer attached to the base film to temporarily fix micro-functional units to the dicing tape.

I further provide a dicing tape including an elastically stretchable base film and an adhesive layer attached to the base film for producing a transfer substrate to temporarily fix micro-functional units in a method of producing a microstructured component including a multiplicity of micro-functional elements on a substrate.

I also provide a system that produces a microstructured component including a multiplicity of micro-functional elements on a substrate, for producing a micro-LED display including a substrate that carries an array of pixel-forming micro-light-emitting diodes on an electrical supply structure, including a control unit; a laser processing station having a laser processing unit controllable by the control unit; a workpiece holding device for receiving a workpiece to be processed; and a workpiece movement system that positions a workpiece to be processed in a processing position of the laser processing station in reaction to movement signals of the control unit, wherein the system includes devices that produce and/or handle a transfer substrate formed by a dicing tape clamped in stretched fashion in a clamping frame and includes an elastically stretchable base film under surface tension and an adhesive layer attached to the base film to temporarily fix micro-functional units to the dicing tape.

### BRIEF DESCRIPTION OF THE DRAWINGS

FIG. 1 shows an unstretched dicing tape mounted on a metal frame.

FIG. 2 shows an expanding operation, in which a dicing tape is stretched and then fixed in the stretched state in a clamping frame.

FIG. 3 shows a finished transfer substrate in accordance with one example.

FIGS. 4 and 5 show two phases of a first transfer step of micro-functional elements from a growth substrate to the transfer substrate (mounting/placement and pressing of the growth substrate by way of the front side thereof onto the transfer substrate).

FIGS. 6 and 7 schematically show components of a laser processing station utilized for a laser lift-off (LLO) between growth substrate and transfer substrate in FIG. 6 and for a laser-induced forward transfer (LIFT) between growth substrate and transfer substrate in FIG. 7.

FIG. 8 shows the laser processing station during the irradiation of a layer composite comprising a transfer substrate at the top with micro-functional elements still adhering thereto and a display substrate at the bottom with a connection structure directed upwards.

FIGS. 9 and 10 schematically show a first transfer step as an LLO step.

FIG. 11 schematically shows a layer composite analogous to FIG. 8 during the irradiation with UV radiation.

FIG. 12 schematically shows a second transfer step as a LIFT step.

### DETAILED DESCRIPTION

My method produces a microstructured component comprising a multiplicity of micro-functional elements on a substrate. In one example, laser processing is carried out in at least one method stage in a laser processing station under the control of a control unit. The method provides for indirectly transferring micro-functional elements from a first substrate to a second substrate with the aid of a transfer substrate. A transfer substrate is a substrate utilized only temporarily, serves as a fabrication aid in the transfer process and is suitable for increasing the flexibility of the transfer.

Micro-functional elements are primarily electrically operable, semiconductor-based components of multilayer construction, e.g. optoelectronic functional elements such as e.g. μLEDs or else light-sensitive sensors, optionally also other electronic components having typical dimensions (length and width or diameter) of a few micrometers to a few hundred micrometers(e.g. 20 μm to 1 mm).

The method involves providing a first substrate carrying a multiplicity of micro-functional elements arranged on a first side of the first substrate in a first spatial arrangement. In a first transfer step, micro-functional elements are transferred from the first substrate to a transfer substrate. In this example, it is possible to transfer all micro-functional elements present on the first substrate by the same transfer step, but optionally also only a subset or a selection of the micro-functional elements such that other micro-functional elements remain on the first substrate for the time being. At a time following that, micro-functional elements are transferred in a second transfer step from the transfer substrate to a second substrate such that the transferred micro-functional elements are arranged on the second substrate in a second spatial arrangement. The second spatial arrangement can correspond to the first spatial arrangement. However, it is also possible to realize a second spatial arrangement that is changed compared to the first spatial arrangement as a result of the indirect transfer by a transfer substrate.

A special characteristic of the method is that the transfer substrate used is a dicing tape clamped in stretched fashion in a clamping frame and comprising an elastically stretchable base film under surface tension with an adhesive layer attached to the base film for temporarily fixing micro-functional units to the dicing tape.

The term “dicing tape” denotes specific elastically expandable or stretchable tapes, for which the term is a customary designation in the field of the production of semiconductor chips. A dicing tape comprises an elastically stretchable base film and an adhesive layer or adhesion layer attached to one side of the base film. The base film can consist e.g. of an elastically stretchable polymer such as e.g. PVC or a polyolefin (PO). The adhesive layer can comprise a single ply or a plurality of plies. Acrylic, for example, can be utilized as adhesive material.

I recognized that commercially available dicing tapes, owing to their intended tasks, have structural and functional properties that can advantageously be utilized in a manner not hitherto known in the production of microstructured components comprising a multiplicity of micro-functional elements on a substrate. Moreover, there are commercially available ancillary devices for handling the dicing tapes. These can be utilized for novel purposes in the context of my methods, if appropriate without modification.

The conventional intended utilization of dicing tapes is in the field of semiconductor chip assembly. Methods and devices have been developed for this field that allow fabrication with extremely high precision in conjunction with high fabrication volume and low costs. A basis for this is the so-called dicing process, wherein a wafer, after lithographic patterning, is singulated e.g. by separating by grinding or dicing into chips (so-called “dies”) and the chips are additionally also prepared in a positionally and locationally accurate manner for the next processing step. Dicing (or separating by grinding) on dicing tape has become established as a dominant process for this fabrication stage. In this example, a dicing tape serves for direct lamination onto the rear side of a wafer. The adhesive layer has an adhesive force suitable for this purpose. The lamination is usually carried out manually or semi-automatically with the aid of a “wafer mounter”.

Afterwards (after the singulating), the elastic dicing tape with the chips adhering thereon is expanded or stretched out uniformly on all sides to enlarge the interspaces between the dies of the diced wafer, thereby to prevent spalling of the chip edges during transport or placement and to facilitate subsequent pick-up operations. After expansion, a clamping frame keeps the dicing tape with the chips or dies adhering thereto in the expanded state. For this purpose, the dicing tape is held by clamping between an inner ring and an outer ring. For mounting dicing tapes onto clamping rings and expanding diced wafers from wafer frames onto clamping rings there are specific dicing ancillary devices, usually referred to as “die matrix expanders” or “expanders”.

A special characteristic of my method consists, then, in a dicing tape clamped in stretched or expanded fashion in a clamping frame being used as transfer substrate. In my use, on account of the clamping in the planar clamping frame, in a manner similar to a taut eardrum, the dicing tape is under a surface tension and, as a result, assumes a planar shape in the otherwise unloaded state such that the stretched dicing tape can form a planar transfer substrate. During the process of clamping it in place, the dicing tape is still empty, i.e. does not yet carry any components. The adhesive layer, which is present anyway in dicing tapes on account of the customary purpose thereof, imparts to the dicing tape adhesion properties that can be utilized in a manner not hitherto known, during the use as a transfer substrate in a production method of the generic type. Specifically, the micro-functional units to be transferred can be fixed to the dicing tape temporarily or for a short while by the adhesive layer and can be released again from the dicing tape as necessary relatively easily. The benefit of this novel concept is increased by the availability of dicing tapes comprising adhesive layers having different adhesive forces such that a dicing tape having an optimum adhesive force for accepting micro-functional units can be selected for any application. Moreover, dicing tapes are available in which the adhesive force of the adhesive layer can be changed in a targeted manner, e.g. by irradiation with ultraviolet light (UV light) and/or thermal treatment. As a result, the adhesive force or the adhesion force can be reduced in a targeted manner as necessary to facilitate the transfer of adhering micro-functional units to some other substrate (in particular to the substrate of the microstructured component to be produced).

In other words, the use of a dicing tape comprises an elastically stretchable base film and an adhesive layer attached to the base film for producing a transfer substrate for temporarily fixing micro-functional elements in a method of producing a microstructured component comprising a multiplicity of micro-functional elements on a substrate.

In the context of the use, the dicing tape in the empty state is areally expanded or stretched out and clamped into a clamping frame such that the dicing tape clamped into the clamping frame is under a surface tension in a useful region surrounded by the clamping frame and forms a planar transfer substrate which is elastically compliant in delimited fashion and which comprises an adhesive layer on a side provided for receiving micro-functional elements.

Preferably, the first substrate is formed by a so-called “growth substrate” and the micro-functional elements are produced on the first substrate. The method thus comprises producing a multiplicity of micro-functional elements in the first spatial arrangement on the first substrate or growth substrate. These are thus transferred to the transfer substrate and fed to further method steps with the aid of the transfer substrate.

The second substrate can already be the substrate of the microstructured component to be produced, e.g. the display substrate of a μLED display. Thus, the method can comprise only exactly a first transfer step (from the growth substrate to the transfer substrate) and a second transfer step (from the transfer substrate to the intermediate product or end product to be produced (the microstructured component)). However, further intermediate steps (one or more) are also possible, for example, using a further transfer substrate such that the production process can also comprise more than two transfer steps.

In any event, the indirect transfer from the growth substrate to the substrate of the microstructured component to be produced using a (at least one) transfer substrate affords the possibility of producing microstructured components in which the number and/or the arrangement of micro-functional elements fitted thereon differ(s) from that number and/or arrangement present during the production of the micro-functional elements. The growth substrate can be a sapphire wafer, for example, i.e. a wafer-type substrate that substantially consists of corundum (aluminium oxide) in high-purity monocrystalline form. However, growth substrates composed of other growth substrate materials are also possible, for example, composed of a semiconductor material such as, for example, a silicon-based semiconductor material or a germanium-based semiconductor material or composed of a glass material.

The dicing tape used may be a UV-sensitive dicing tape, i.e. a dicing tape comprising an adhesive layer, the adhesion force of which vis-à-vis solid bodies can be lowered by way of irradiation by ultraviolet light from a first adhesion force present in the unirradiated state to a second adhesion force reduced compared to the first adhesion force. This property can be beneficial especially in the second transfer step to facilitate the detachment of the micro-functional elements to be transferred from the transfer substrate to the second substrate.

The dicing tape used may be a thermal release dicing tape comprising an adhesive layer, the adhesion force of which vis-à-vis solid bodies can be lowered by way of heating from a first adhesion force present at room temperature to a second adhesion force reduced compared to the first adhesion force. The detachment of the micro-functional elements to be transferred from the transfer substrate can then be facilitated by an upstream thermal treatment.

In the context of the first transfer step, preferably in a bonding step, the transfer substrate is connected to the first substrate carrying the micro-functional elements to form a composite arrangement by free surfaces of the micro-functional elements facing away from the first substrate being brought into adhesion contact with the adhesive layer of the dicing tape under the action of a press-on force. For this bonding step there are various external influencing possibilities for setting the resulting adhesion strength or adhesion force between the micro-functional elements to be transferred and the (self-adhesive) transfer substrate. First, there is the possibility of constructing the transfer substrate with a dicing tape whose adhesive layer already brings a suitable adhesion force with respect to the material of the surfaces of the micro-functional elements. Moreover, the adhesion strength can be influenced by way of the press-on force during bonding such that in a process-dependent manner numerous optimization possibilities exist in the course of the bonding step.

Provision is preferably made for the first transfer step, i.e. the transfer of micro-functional elements from the first substrate to the transfer substrate, to comprise an irradiation with laser radiation in a laser processing station, (preferably as an LLO process) wherein an adhesion force between the first substrate and the micro-functional elements to be transferred is reduced by spatially selective or area-covering laser radiation.

In this example, the laser irradiation is preferably carried out such that, as a result, the adhesion force acting between the first substrate and the micro-functional elements to be transferred becomes less than the adhesion force acting between the micro-functional elements to be transferred and the adhesive layer. Preferably, in this example, ultraviolet laser radiation having a wavelength of less than 360 nm is used, for example, laser radiation of a 248 nm excimer laser.

The laser processing can be carried out such that solely as a result of the laser irradiation the connection between the micro-functional elements to be transferred and the first substrate is weakened to an extent such that when the transfer substrate is detached from the composite arrangement, the micro-functional elements to be transferred are taken along without exception.

In other examples, it can be expedient, in addition to the laser irradiation, to subject the composite arrangement to a thermal treatment, wherein a temperature profile and a duration of the thermal treatment are designed such that the adhesion force acting between the first substrate and the micro-functional elements to be transferred is reduced by the thermal treatment.

In each of these examples, at the conclusion of the first transfer step, the transfer substrate provided with transferred micro-functional units is detached from the first substrate and possibly from micro-functional units remaining thereon with separation of the connection between the transferred micro-functional units and the first substrate.

It is also possible to carry out the first transfer step by way of a LIFT method. Touching contact between the micro-functional elements of the growth substrate and the transfer substrate is not required for this purpose. Alternatives with LIFT for the first transfer step may be preferred e.g. if the first and second spatial arrangements of the micro-functional elements are intended to be different.

Alternatively, provision is made for transferring micro-functional elements in the second transfer step from the transfer substrate to the second substrate to be carried out in a laser processing station under the action of laser radiation. In particular, for this purpose method examples of laser-induced forward transfer (LIFT), which is known per se, can be utilized by way of individual or all micro-functional units carried by the transfer substrate being transferred from the transfer substrate serving as initial substrate or donor substrate to a target substrate or an acceptor, in particular to the second substrate, by laser radiation.

However, it is not mandatory to carry out the transfer of micro-functional elements in the second transfer step using laser radiation. Provision may be made for a bonding step to be carried out in the second transfer step without the use of laser radiation by way of the transfer substrate with the micro-functional elements to be transferred being connected to the second substrate to form a composite arrangement by way of free surfaces of the micro-functional elements facing away from the transfer substrate being brought into adhesion contact with an adhesive layer of the second substrate and the connection between the micro-functional elements to be transferred and the transfer substrate then being released.

This can be realized e.g. using a UV dicing tape as a transfer substrate, the adhesion force of which can be sufficiently reduced by irradiation with the aid of a suitable UV lamp. Optionally, it is also possible to use a dicing tape whose adhesion force is significantly lower than the adhesion force of the adhesive layer of the second substrate. The tape can then be pulled off without the adhesion force being reduced. Optionally, for this purpose it is possible to use standard dicing tapes whose adhesion is high enough to firmly hold the die during dicing, but low enough for the die to easily be removed by die bonders or Pick & Place devices. If necessary, aids known per se can be used to gently pull off a dicing tape.

I also provide a system for producing a microstructured component. The system comprises a control unit, a laser processing station having a laser processing unit controllable by the control unit, a workpiece holding device that receives a workpiece to be processed, and also a workpiece movement system that positions a workpiece to be processed in a processing position of the laser processing station in reaction to movement signals of the control unit. The system is characterized by devices that produce and handle a transfer substrate comprising a dicing tape clamped in stretched fashion in a clamping frame and comprising an elastically stretchable base film under surface tension with an adhesive layer attached to the base film to temporarily fix micro-functional units to the dicing tape.

The devices can comprise one or more of the following components: a wafer mounter that mounts an unstretched dicing tape onto a frame and also mounts the growth substrate onto the already stretched dicing tape; a die matrix expander that stretches and mounts dicing tapes onto a clamping frame; a heating system that reduces the adhesion force between the growth substrate and the micro-functional units and/or reduces the adhesion force of thermal dicing tapes; a UV lamp that reduces the adhesion force of UV-sensitive dicing tapes.

Further advantages are evident from the description of examples explained below with reference to the figures.

Examples of my methods and systems of producing microelectronic components using laser processing methods are presented below. The microelectronic components each comprise a multiplicity of micro-functional elements applied on a substrate. The field of application of primary importance in the examples is the production of a micro-LED display. Such a display comprises a substrate (display substrate) that carries an array of micro-light-emitting diodes (μLEDs) that are intended to form the individual picture elements or pixels of the display. The latter are applied on an electrical supply structure. The micro-LEDs are optoelectronic micro-functional elements of multilayer construction.

Laser processing is carried out in at least one method stage in a laser processing station. The laser processing may also be referred to as laser micro-processing since it can be used to process and/or produce fine structures having typical structure sizes of the order of magnitude of one micrometer or a few micrometers.

In the examples explained below, commercially available dicing tapes are utilized in a novel use, namely as a transfer substrate.

The traditional process of connecting a dicing tape to a wafer involves a temporary connection that was controlled to the effect that it is possible for the dicing tape to be removed without any residues after wafer processing. Moreover, dicing tapes are designed such that they can expand/stretch by a considerable amount without tearing. Expansions by at least 100% are normally possible. Maximum expansions can be up to 300% or up to 500% or more.

One advantage of my use of dicing tapes is that they were developed for application in microelectronics, in ultraclean environments and with extremely high precision with regard to dimensions and properties and are available with correspondingly high quality and in large quantities (e.g. as roll goods) in a cost-effective way. Furthermore, industrial solutions in the form of dicing ancillary devices for applying and stretching (expanding) the tapes are commercially available both as manual and as automated solutions.

I recognized that with dicing tapes a highly developed product is available that can advantageously be used as a temporary carrier or as a transfer substrate. By contrast, the development of a dedicated tape or a dedicated adhesive for temporarily mounting the wafers for μ-LED transfer would cause high costs and mean time-consuming development. These costs can be saved so that the fabrication of the components produced is realized more cost-effectively than hitherto with the quality of the end product at least remaining constant.

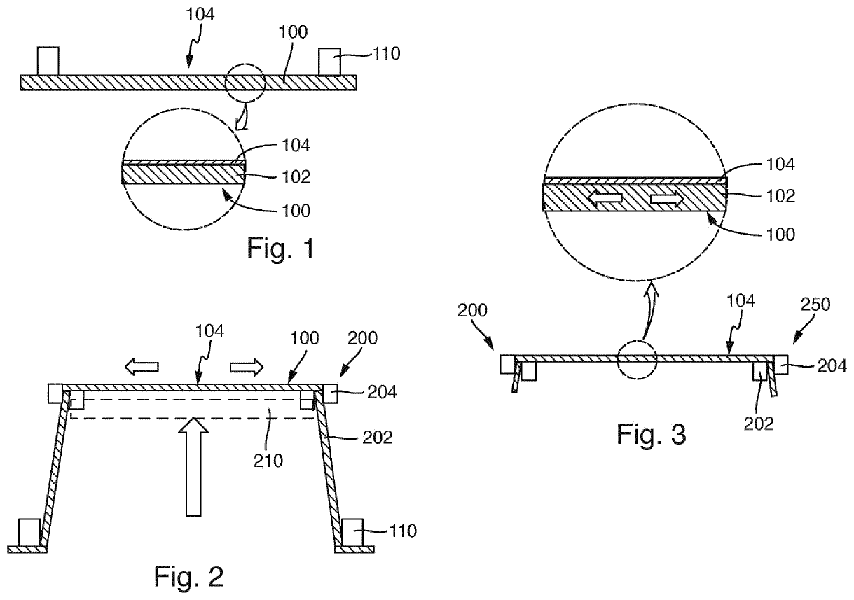

First, preparatory method steps of producing a transfer substrate 250 (finished transfer substrate in FIG. 3) will be explained with reference to FIGS. 1 to 3.

The dicing tape 100 used in FIG. 1 comprises an elastically stretchable base film 102 that can consist e.g. of an elastically stretchable polymer such as e.g. PVC. An adhesive layer 104 or adhesion layer, which can be constructed as a single ply or a plurality of plies, is applied to one side of the base film 102. Typical tape thicknesses (base film plus adhesive layer) can be e.g. 80 μm to 150 μm, the adhesive layer taking up only a fraction of the total tape thickness (e.g. 10 μm to 20 μm).

In the example described here, the dicing tape 100 is first mounted by way of the adhesive side 104 onto a planar ring-shaped metal frame 110 with the aid of a wafer/film frame tape applicator (not illustrated, but known to those skilled in the art). A framed dicing tape 100 is then present, i.e. a flexible dicing tape 100 stabilized by the metal frame 110 (FIG. 1). The dicing tape 100, which is not yet under tension, rests in a smooth manner, but may become deformed in the event of loading. By way of example, the weight of a mounted epitaxial wafer would lead to sagging.

So that the dicing tape 100 remains dimensionally stable even in the event of loading, in the second step it is stretched or expanded on all sides using a die matrix expander (not illustrated in its entirety, but known to those skilled in the art). This expanding operation is also referred to as “stretching” and is illustrated schematically in FIG. 2. For this purpose, first, a preferably circularly closed holding ring 202 (e.g. composed of plastic) is inserted into the vertically movable ram 210 of the die matrix expander. Then, the framed dicing tape 100 is inserted and the frame 110 is fixed in the die matrix expander. Afterwards, the ram 210 with the holding ring 202 inserted therein is moved upwards by a defined amount relative to the metal frame 110, with the result that the dicing tape 100 experiences the desired expansion and is under a surface tension acting uniformly in all directions. The expansion can be 100% or more, e.g. 200% to 500%, optionally even more than that or less than that.

A second holding ring 204 (e.g. a plastic ring) is then provided, the internal diameter of which is minimally larger than the external diameter of the first holding ring 202. The second holding ring is pushed tautly onto the edge of the dicing tape 100 such that the dicing tape 100 is clamped under tension between the two plastic rings (first holding ring or inner ring 202 and second holding ring or outer ring 204) and does not relax again after removal. The outer parts of the dicing tape with the frame 110, which are not held under tension, are now cut off and the inner tensioned dicing tape held under surface tension by the two rings 202, 204 is removed.

The two holding rings (inner ring 202, outer ring 204) form a torsionally rigid clamping device 200, which holds the dicing tape 100 in the region enclosed by the rings or the clamping device under surface tension on all sides in a manner similar to that of a taut eardrum. In the absence of external forces, the tensioned thin dicing tape assumes a planar shape. It can now be used as a transfer substrate.

FIG. 3 shows the finished transfer substrate 250 and an enlarged detail excerpt illustrating the layer structure of the transfer substrate 250. The planar transfer substrate 250 is formed by the dicing tape 100 clamped in stretched fashion in the planar clamping frame 200 and hence under surface tension, the dicing tape comprising an elastically stretched base film 102 and the adhesive layer 104 attached to one side thereof. Alternatively, this transfer substrate 250 can be used as a temporary carrier for micro-functional elements in the context of transferring micro-functional elements between other substrates.

It is possible for the adhesive layer 104 of the dicing tape 100 (in the region where the first substrate is mounted later) still to bear a thin protective film during these production steps, which protective film protects the adhesive side of the dicing tape against contamination and damage and is removed only before the use of the transfer substrate. For this purpose, generally the liner (protective film) is cut selectively in a circular manner by a knife or laser, for example, such that during subsequent pulling off only the outer region of the liner is removed (for the purpose of mounting the frame and the clamping rings) and the region where the first substrate is mounted later still remains protected. Alternatively, the liner can also be pulled off in its entirety and a prepared circular piece of the protective film can be applied anew.

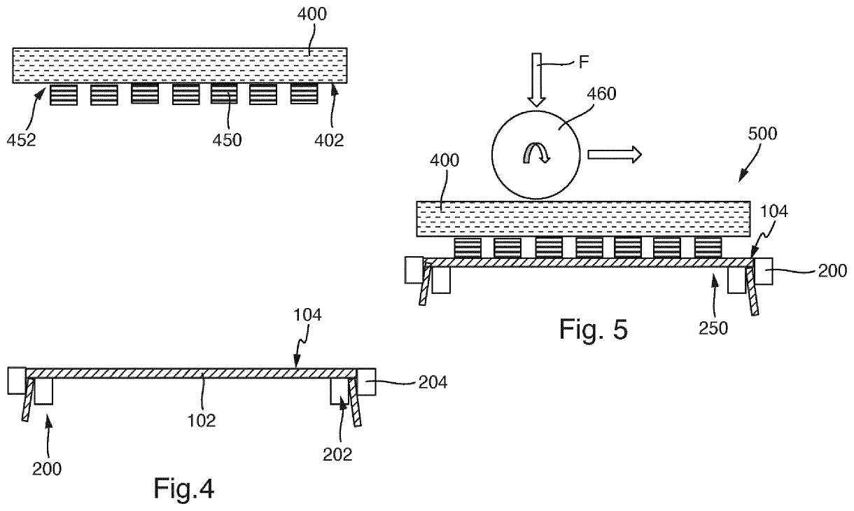

A first transfer step is explained below with reference to FIGS. 4 and 5, in which first transfer step micro-functional elements 450 in the form of μLEDs of multilayer construction are transferred from a first substrate 400 to the transfer substrate 250. In preparation for this, a first substrate 400, in the form of a growth substrate 400, may be provided, which carries a multiplicity of micro-functional elements 450 arranged on a first side 402 of the first substrate 400 in a first spatial arrangement.

FIG. 4 shows in the upper part a growth substrate 400 in the form of a flat sapphire wafer. By epitaxial growth, p-doped and n-doped semiconductor layers composed of gallium nitride (GaN) are formed on the front side 402 (first side) of the growth substrate 400, the front side having been processed in planar fashion with high precision. The growth substrate is therefore also referred to as an epitaxial wafer. In the boundary region with respect to the growth substrate 400, a thin buffer layer 452 is formed. The buffer layer can be a separate layer, e.g. composed of undoped GaN, or a thin partial layer of the first GaN layer. The GaN layers generally each have a thickness of a few μm. The total thickness of the various GaN layers can be e.g. less than 10 μm. Before further processing, the GaN layers can be structured, for example, by laser processing to produce individual components or prepare the production thereof.

A connection layer having a thickness of generally a few μm is applied to the GaN layer stack, for example, by vapor deposition. The connection layer can consist e.g. of gold, platinum, chromium or other metals. With the aid of the connection layer, the growth substrate 400 with the micro-functional elements 450 situated thereon, i.e. the GaN layer stacks, is connected to the adhesively acting adhesive layer 104 of the transfer substrate 250. This mounting step is carried out semiautomatically with the aid of a wafer/film frame tape applicator. For this purpose, first, the dicing tape 100 is inserted with the adhesive surface or the adhesive layer 104 facing upwards. The wafer with the μ-LED dies is then positioned with respect to the adhesive surface of the tape (FIG. 4). The wafer is then pressed fixedly onto the adhesive surface of the dicing tape 100 under a press-on force F with the aid of a roller 460 (FIG. 5).

This gives rise to the workpiece 500 shown in FIG. 5 in the form of a mounted wafer, i.e. a layer composite comprising the growth substrate 400 and the micro-functional elements 450 grown thereon, which adhere to the adhesive layer 104 of the transfer substrate 250 by way of their free top sides.

The mounted wafer is then inserted into the workpiece holding device of a laser processing station 600 for the LLO process. The workpiece holding device has at its top side a ring-shaped accommodating groove to be able to accommodate the clamping frame 200 of the workpiece 500 in a positionally defined manner.

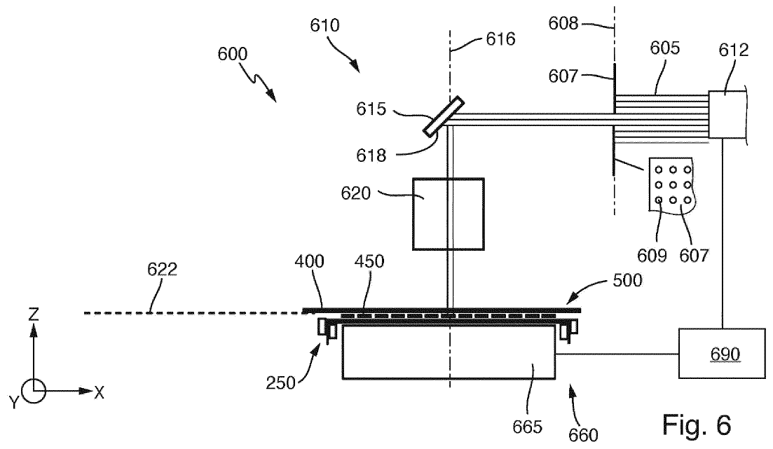

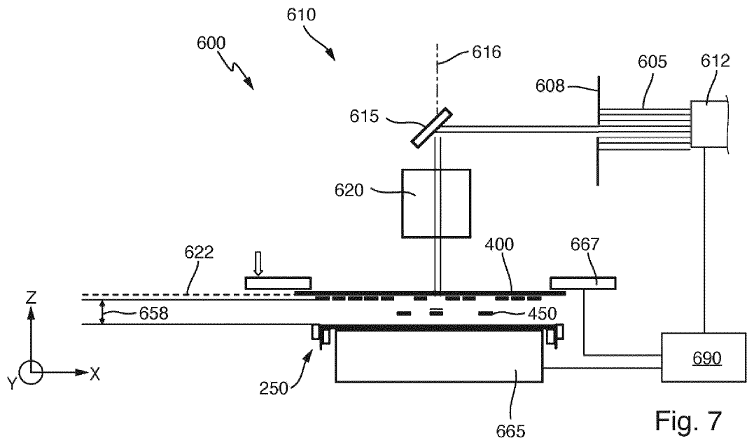

FIGS. 6 and 7 schematically show some components of a suitable laser processing station 600. The laser processing station is configured for the method of laser lift-off (LLO) between growth substrate and transfer substrate in FIG. 6, and for laser-induced forward transfer (LIFT) between growth substrate and transfer substrate in FIG. 7.

The laser processing station 600 comprises a laser processing unit 610, which works with laser radiation of a laser radiation source 612 in the form of a KrF excimer laser, which emits a laser beam 605 with a laser wavelength of approximately 248 nm, i.e. laser radiation in the deep ultraviolet range (DUV). The laser beam is radiated in in a horizontal direction parallel to the x-axis of the system coordinate system.

The laser beam expanded and/or conditioned in some other way passes through a mask 607 arranged in a mask plane 608 and comprising a grid arrangement of apertures or openings 609 that each transmit partial beams such that a group of partial beams emerges. This enables parallel processing (simultaneous processings at a multiplicity of locations on the workpiece). The mask can have hundreds or thousands of mask openings 609 generally fashioned in an identical way (cf. detail). The mask openings can be of various shapes, e.g. square, inequilateral rectangular or the like.

The rays in the partial beams are deflected at a beam deflection device 615 and then propagate substantially vertically or parallel to a principal axis 616 of the laser processing unit 610 (parallel to the z-direction) or at more or less acute angles with respect thereto downwards in the direction of a workpiece 500 to be processed. The beam deflection device 615 has a plane-parallel substrate consisting of synthetic fused silica, at which a plane surface is a reflective beam deflection surface 618 by virtue of it being coated with a dielectric coating that is highly reflective for the laser radiation. The arrangement of illuminated mask openings 609 in the mask plane 608 is imaged into the processing plane 622 of the laser processing unit 610 with the aid of an imaging lens 620. The optical axis of the imaging lens 620 defines or corresponds to the principal axis 616 of the laser processing unit. The imaging can be magnifying, reducing or size-maintaining (1:1 imaging). In the example, the same intensity distribution as in the mask plane is present in the processing plane, but reduced in scale.

The laser processing station 600 comprises a workpiece movement system 660 designed to position a workpiece to be processed in a desired processing position of the laser processing station in reaction to movement signals of the control unit 690.

In the configuration in FIG. 6, the workpiece movement system 660 comprises a first substrate table 665 that serves as a workpiece holding device and which can be moved parallel to the (horizontal) x-y-plane of the system coordinate system and also in the height direction (parallel to the z-direction) very accurately to a desired position and can also be rotated about a vertical rotation axis (phi axis). For this purpose, precisely controllable electrical direct drives are provided in the example.

In the configuration in FIG. 7, a second substrate table 670 is arranged above the first substrate table 665 and can likewise be moved in a controlled manner in any desired directions horizontally (parallel to the x-y-plane) and also vertically (parallel to the z-direction) and can also be rotated about a vertical axis. The laser processing station 600 can contain both substrate tables, but in the method stage in FIG. 6 the second substrate table is not utilized and is therefore not illustrated.

The mask 607 is carried by a mask movement system (not illustrated), which, under the control of the control unit, allows a displacement of the mask 607 in the mask plane 608 (parallel to the y-z-plane) and also a rotation of the mask about an axis parallel to the z-direction.

In the configuration in FIG. 6, the laser processing station 600 is designed for laser lift-off (LLO). The mounted wafer, i.e. the workpiece 500 in the form of the areal composite comprising transfer substrate 250 and growth substrate 400 and also the micro-functional elements 450 arranged between the substrates and held thereon, is then inserted into the workpiece holding device of the laser processing station for the LLO process. In this example, the rear side of the growth substrate 400 is directed upwards and serves as an entrance surface for the laser radiation.

Afterwards, the LLO process is carried out. In the example, all dies are irradiated locally, i.e. only the dies, not the interspaces.

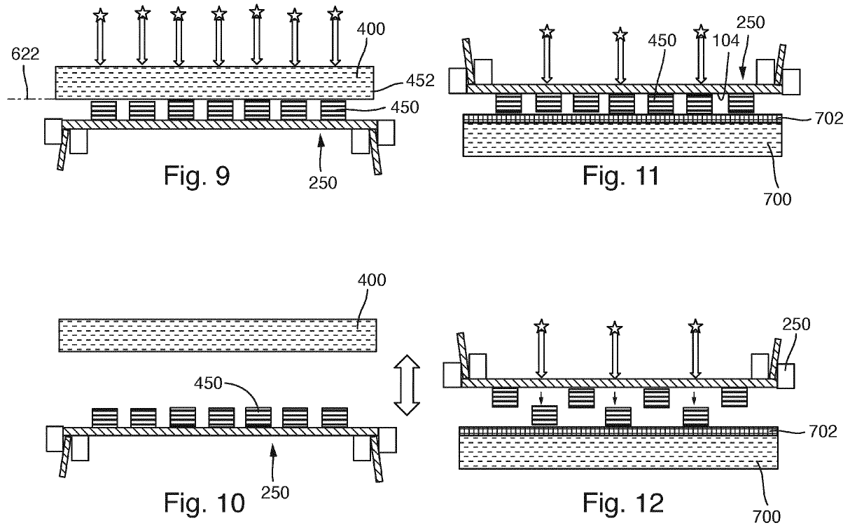

FIG. 6 shows the workpiece or the arrangement before the release of the areal connection (also cf. FIG. 9). The upper flat substrate 400 is the growth substrate 400, which is also referred to as donor substrate in this example because later it donates the micro-functional elements 450 applied thereon. The transfer substrate 250 bearing on the first substrate table 665 here functions as acceptor substrate because it accepts or receives the functional elements 450. The acceptor substrate (transfer substrate 250) with the GaN stacks carried thereby then serves as a basis for the further steps of producing the microelectronic component.

In the laser lift-off method, the workpiece 500 is positioned such that the processing plane 622 lies in the region between the donor substrate 400 and the GaN elements 450 to release the areal connection therebetween by laser processing. In this example, the buffer layer 452, situated in the boundary region between the growth substrate and the GaN elements is destroyed by laser radiation (or decomposed to leave a thin Ga layer and gaseous nitrogen). In this example, the laser irradiation is effected through the laser-transparent growth substrate 400.

It is possible for the connection in the region of the buffer layer to be weakened solely by the laser irradiation to an extent such that the growth substrate and the transfer substrate with the transferred micro-functional elements adhering thereto can easily be separated from one another (cf. FIG. 10).

Alternatively, the composite comprising growth substrate 400 with the μLEDs and the tensioned dicing tape is subjected to a thermal treatment (heat treatment) after the LLO. This is preferably effected at a temperature of approximately 50° C. for approximately 10 minutes. As a result, the connection between epitaxial wafer and μLEDs is weakened further such that the epitaxial wafer can be removed with relatively little force action (with the heat treatment temperature being maintained). The temperature is then gradually cooled to room temperature.

Depending on the type of method, the UV irradiation during the LLO can also be effected over a large area, for example, by a scanned line beam, provided that in the interspaces between the μLEDs no damage occurs e.g. on the acceptor substrate. It is also possible to scan a square beam (in the X- and Y-direction).

The tape (the dicing tape 100) is stretched at the beginning. A tautly tensioned tape (as in a drum) is then present that serves as a transfer substrate and which behaves in a similar manner to a plate such that the positions of the dies no longer change after the removal of the epitaxial wafer 400 and the high accuracy required is ensured. The μLEDs used in the example in FIGS. 5 and 6 are RGB LEDs such that there is only one type of epitaxial wafer.

In the configuration in FIG. 7, the laser processing station 600 is designed for a LIFT process to transfer the μLEDs from the growth substrate 400 (donor) via a certain free flight path to the adhesive side of the transfer substrate 250 (acceptor). The latter is held in position by the first substrate table 655; the adhesive top side to be equipped with laser diodes is directed upwards. The growth substrate 400, which is transparent to the laser radiation, is held by the second substrate table 667 and carries the micro-electronic functional elements 450 directed downwards. By laser beams being radiated in positionally accurately, the micro-LEDs to be transferred are then detached from the donor substrate 400 and transferred to the acceptor substrate 250. The donor-acceptor spacing 658, which is a measure of the flight range of the micro-functional elements 450 to be transferred, is generally 30 μm to 500 μm, in particular 80 μm to 200 μm.

The LIFT process is particularly suitable for transferring only a selected subset of micro-functional elements to the transfer substrate 250. If the transfer from the epitaxial wafer to the dicing tape is effected by the LIFT, e.g. it is also possible to transfer μLEDs from three different epitaxial wafers (red, green and blue).

In preparation for the second transfer step, the dicing tape (the transfer substrate) with the μLEDs is then removed and turned over such that the micro-functional elements 450 face downwards. Afterwards, the μLEDs are bonded onto the second substrate 700, i.e. onto a display front glass in the example, e.g. by an adhesive.

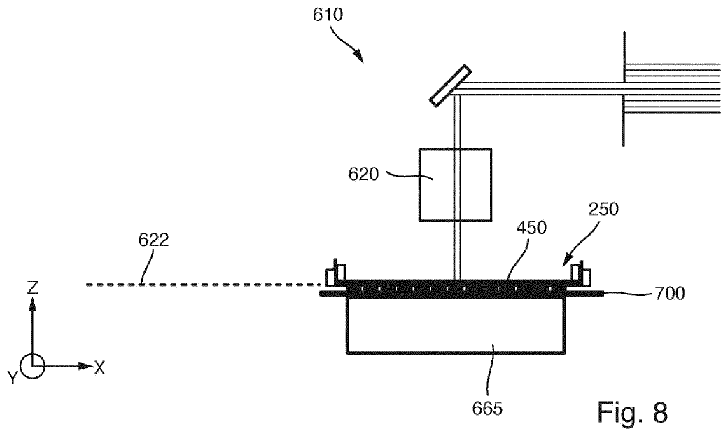

FIG. 8 shows the configuration of the resultant layer composite after bonding and after placement onto the substrate table of the laser processing station 600. The transfer substrate 250 with the micro-functional elements still adhering thereto is now at the top, and the front glass 700 at the bottom. In this example, the μLEDs are mounted onto the front glass and the front glass with the μLEDs is contacted with the backplane in a later processing step. As a result, the backplane is not exposed to UV radiation. It is also possible for the display front glass 700 with the connection structure (backplane) 702 directed upwards to be arranged at the bottom and for the μLEDs to be bonded onto the backplane.

In the next step (cf. FIG. 8 or FIG. 11), the UV dicing tape (the transfer substrate) is irradiated with UV photons (small star symbol) from its rear side situated at the top. As a result, the adhesion strength of the adhesive layer facing downwards is drastically reduced such that it can be detached from the μLEDs with little force action.

A large-area irradiation by a suitable UV lamp is generally suitable for this purpose. Alternatively, the positions at which the dies are situated can also be selectively irradiated again by UV lasers if this significantly facilitates detachment or if selective detachment of a portion of the μLEDs is required.

The method can also be modified depending on μLED technology. In this regard, the transfer of the μLEDs from the transfer substrate 250 (from the dicing tape) to the second substrate (here e.g. the display substrate 700 with backplane) can also be effected by LIFT (cf. FIG. 12). If necessary, an additional transfer step can be inserted to provide the correct orientation of the μLEDs on the display.

1.-14. (canceled)

15. A method of producing a microstructured component comprising a multiplicity of micro-functional elements on a substrate for producing a micro-LED display comprising a substrate that carries an array of pixel-forming micro-light-emitting diodes on an electrical supply structure, wherein laser processing is carried out in at least one method stage in a laser processing station under control of a control unit, the method comprising:
providing a first substrate that carries a multiplicity of micro-functional elements arranged on a first side of the first substrate in a first spatial arrangement;
transferring micro-functional elements in a first transfer step from the first substrate to a transfer substrate; and
transferring micro-functional elements in a second transfer step from the transfer substrate to a second substrate such that the micro-functional elements are arranged on the second substrate in a second spatial arrangement,
wherein
the transfer substrate is a dicing tape clamped in stretched fashion in a clamping frame and comprises an elastically stretchable base film under surface tension with an adhesive layer attached to the base film to temporarily fix micro-functional units to the dicing tape.

16. The method according to claim 15, wherein the first substrate is a growth substrate and the micro-functional elements are produced on the first substrate and/or the second substrate is the substrate of the microstructured component.

17. The method according to claim 15, wherein the dicing tape is a UV-sensitive dicing tape comprising an adhesive layer, an adhesion force of which vis-à-vis solid bodies can be lowered by way of irradiation by ultraviolet light from a first adhesion force present in the unirradiated state to a second adhesion force reduced compared to the first adhesion force, or the dicing tape is a thermal release dicing tape comprising an adhesive layer, the adhesion force of which vis-à-vis solid bodies can be lowered by way of heating from a first adhesion force present at room temperature to a second adhesion force reduced compared to the first adhesion force.

18. The method according to claim 15, wherein, during the first transfer step, in a bonding step, the transfer substrate is connected to the first substrate carrying the micro-functional elements to form a composite arrangement by free surfaces of the micro-functional elements facing away from the first substrate being brought into adhesion contact with the adhesive layer of the dicing tape under action of a press-on force.

19. The method according to claim 15, wherein the first transfer step comprises an irradiation of the composite arrangement with laser radiation in a laser processing station, an adhesion force between the first substrate and the micro-functional elements to be transferred is reduced by spatially selective or area-covering laser radiation, the laser irradiation is carried out such that as a result the adhesion force acting between the first substrate and the micro-functional elements to be transferred becomes less than the adhesion force acting between the micro-functional elements to be transferred and the adhesive layer and/or ultraviolet laser radiation having a wavelength of less than 360 nm or laser radiation of a 248 nm excimer laser is used.

20. The method according to claim 19, wherein, in addition to the laser irradiation, the composite arrangement is subjected to a thermal treatment, and a temperature profile and a duration of the thermal treatment are designed such that the adhesion force acting between the first substrate and the micro-functional elements to be transferred is reduced by the thermal treatment.

21. The method according to claim 15, wherein, at a conclusion of the first transfer step, the transfer substrate provided with transferred micro-functional units is detached from the first substrate and possibly from micro-functional units remaining thereon with separation of the connection between the transferred micro-functional units and the first substrate.

22. The method according to claim 15, wherein the first transfer step is carried out by a LIFT method without touching contact between the micro-functional elements of the first substrate and the transfer substrate, and the first spatial arrangement and the second spatial arrangement of the micro-functional elements differ from one another.

23. The method according to claim 15, wherein transferring micro-functional elements in the second transfer step from the transfer substrate to the second substrate is carried out in a laser processing station under action of laser radiation, and a method comprising:
(i) a laser-induced forward transfer (LIFT) is utilized by way of individual or all micro-functional units carried by the transfer substrate being transferred from the transfer substrate via a flight path to the second substrate, provided with an adhesion layer, by laser radiation, or
(ii) a laser lift-off transfer (LLO) is utilized by way of the micro-functional units carried by the transfer substrate first being bonded onto the second substrate and by way of the adhesion force of individual or all micro-functional units carried by the transfer substrate to the transfer substrate being reduced by UV laser radiation such that the transfer substrate can be removed with little force action,
is selected.

24. The method according to claim 15, wherein transferring micro-functional elements in the second transfer step from the transfer substrate to the second substrate is carried out in a processing station by way of the micro-functional units carried by the transfer substrate first being bonded onto the second substrate and by way of the adhesion force of the micro-functional units carried by the transfer substrate to the transfer substrate being reduced by UV radiation or a UV lamp, or a temperature increase, or by contact heating or thermal radiators such that the transfer substrate can be removed with little force action.

25. A dicing tape comprising an elastically stretchable base film and an adhesive layer attached to the base film for producing a transfer substrate to temporarily fix micro-functional units in a method of producing a microstructured component comprising a multiplicity of micro-functional elements on a substrate.

26. The dicing tape according to claim 25, which is areally expanded and clamped into a clamping frame such that the dicing tape clamped into the clamping frame is under a surface tension in a useful region surrounded by the clamping frame and forms a planar transfer substrate that is elastically compliant in delimited fashion and comprises an adhesive layer on a side provided for receiving micro-functional elements.

27. A system that produces a microstructured component comprising a multiplicity of micro-functional elements on a substrate, for producing a micro-LED display comprising a substrate that carries an array of pixel-forming micro-light-emitting diodes on an electrical supply structure, comprising:
a control unit;
a laser processing station having a laser processing unit controllable by the control unit;
a workpiece holding device for receiving a workpiece to be processed; and
a workpiece movement system that positions a workpiece to be processed in a processing position of the laser processing station in reaction to movement signals of the control unit, wherein
the system comprises devices that produce and/or handle a transfer substrate formed by a dicing tape clamped in stretched fashion in a clamping frame and comprises an elastically stretchable base film under surface tension and an adhesive layer attached to the base film to temporarily fix micro-functional units to the dicing tape.

28. The system according to claim 27, wherein the devices that produce and/or handle a transfer substrate comprise one or more of:
(i) a wafer/film frame tape applicator that mounts an unstretched dicing tape onto a frame and also mounts the first substrate onto the already stretched dicing tape;
(ii) a die matrix expander that stretches and mounts dicing tapes onto a clamping frame;
(iii) a heating system that reduces adhesion force between the first substrate and the micro-functional units and/or reduces adhesion force of thermal dicing tapes;
(iv) a UV lamp that reduces adhesion force of UV-sensitive dicing tapes; and
(v) a device that produces a bonding connection between the micro-functional units on the transfer substrate and the second substrate.
